(19) United States
(12) Patent Application Publication
(10) Pub. No.: US 2024/0321556 A1
(43) Pub. Date: Sep. 26, 2024

(54) ETCHING METHOD AND PLASMA PROCESSING APPARATUS

(71) Applicant: Tokyo Electron Limited, Tokyo (JP)

(72) Inventor: Yoshinari HATAZAKI, Kurokawa-gun (JP)

(73) Assignee: Tokyo Electron Limited, Tokyo (JP)

(21) Appl. No.: 18/611,755

(22) Filed: Mar. 21, 2024

(30) Foreign Application Priority Data
Mar. 23, 2023 (JP) 2023-046455

(51) Int. Cl. H01J 37/32

(52) U.S. Cl. CPC H01J 37/32449; H01J 2237/332; H01J 2237/334

(57) ABSTRACT

An etching method comprising (a) providing a substrate including a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region, (b) forming a deposit on the shoulder portion with first plasma generated from a first process gas containing a gas containing carbon and oxygen, and (c) etching a bottom portion of the recess with second plasma generated from a second process gas different from the first process gas.

### CROSS-REFERENCE TO RELATED APPLICATION

This application is based upon and claims the benefit of priority from Japanese Patent Application No. 2023-046455, filed on Mar. 23, 2023, the entire contents of which are incorporated herein by reference.

### FIELD

Exemplary embodiments of the present disclosure relate to an etching method and a plasma processing apparatus.

### BACKGROUND

Japanese Unexamined Patent Application Publication No. 2020-119918 discloses a technique for etching a bottom portion of a recess with respect to a film including the recess and a substrate having a mask provided on the film. In Japanese Unexamined Patent Application Publication No. 2020-119918, a deposit is selectively formed on the mask, and then the bottom portion of the recess is etched.

### SUMMARY

In an exemplary embodiment, an etching method includes (a) providing a substrate including a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region; (b) forming a deposit on the shoulder portion with first plasma generated from a first process gas containing a gas containing carbon and oxygen; and (c) etching a bottom portion of the recess with second plasma generated from a second process gas different from the first process gas.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a schematic diagram illustrating a plasma processing apparatus according to an exemplary embodiment.

FIG. 2 is a schematic diagram illustrating the plasma processing apparatus according to an exemplary embodiment.

FIG. 3 is a flowchart illustrating an etching method according to an exemplary embodiment.

FIG. 4 is a cross-sectional view of an example of a substrate to which the method in FIG. 3 may be applied.

FIG. 5 is a cross-sectional view illustrating a step of the etching method according to the exemplary embodiment.

FIG. 6 is a cross-sectional view illustrating another step of the etching method according to the exemplary embodiment.

FIG. 7 is a cross-sectional view illustrating still another step of the etching method according to the exemplary embodiment.

FIG. 8 is a cross-sectional view of a substrate according to a modification example, to which the method in FIG. 3 may be applied.

FIG. 9 is a cross-sectional view illustrating still yet another step of the etching method according to the exemplary embodiment.

FIG. 10 is a schematic diagram illustrating a substrate processing system according to the exemplary embodiment.

### DETAILED DESCRIPTION

Hereinafter, various exemplary embodiments will be described in detail with reference to the drawings. In the drawing, the same or equivalent portions are denoted by the same reference symbols.

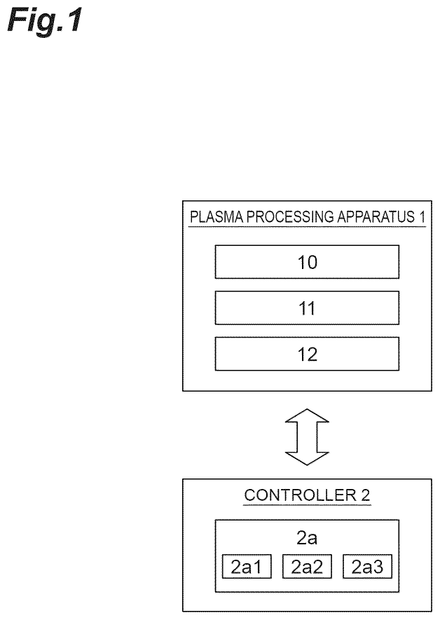

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

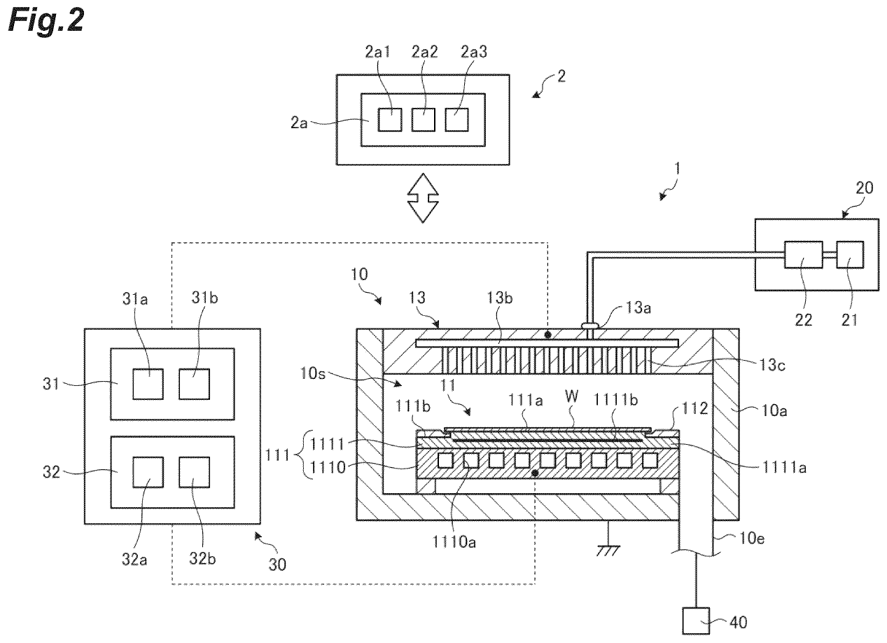

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

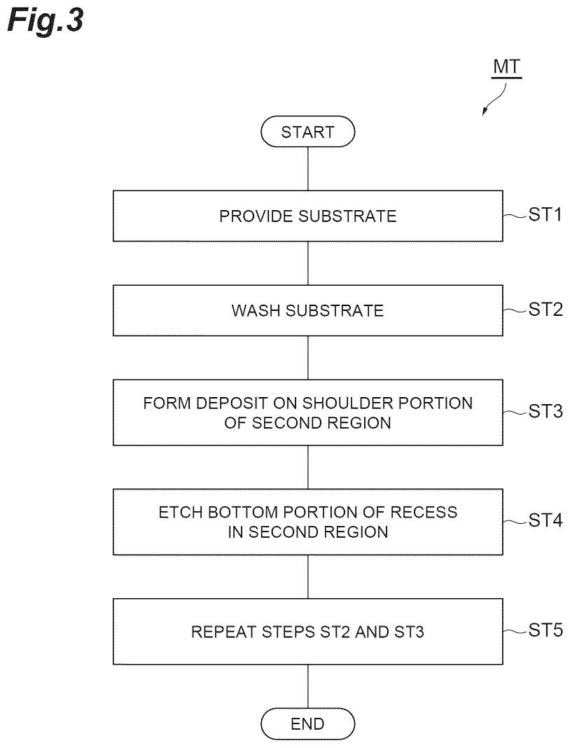

FIG. 3 is a flowchart illustrating an etching method according to an exemplary embodiment. An etching method MT (referred to as a “method MT” below) illustrated in FIG. 3 can be performed by the plasma processing apparatus 1 in the above embodiment. The method MT may be applied to the substrate W.

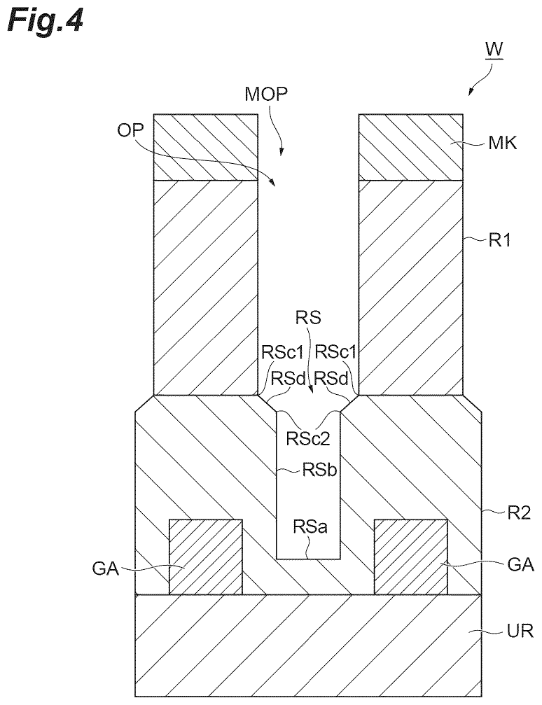

FIG. 4 is a cross-sectional view of an example of the substrate W to which the method MT may be applied. The substrate W includes a first region R1 having an opening OP and a second region R2 located below the first region R1. The second region R2 includes a recess RS communicating with the opening OP. The recess RS includes a bottom portion RSa and a side wall RSb. The opening OP and the recess RS may have a hole pattern or a line pattern.

The first region R1 may contain silicon (Si). The first region R1 may contain silicon and oxygen (O). The first region R1 may contain silicon oxide (SiOₓ). x is a positive real number.

The second region R2 includes a shoulder portion RSd located in the opening OP when viewed from a direction perpendicular to the main surface of the substrate W. The direction perpendicular to the main surface of the substrate W may be a direction perpendicular to a surface direction of the substrate W, may be a thickness direction of the substrate W, or may be a direction from the first region R1 to the second region R2. The shoulder portion RSd may be exposed when viewed from the direction perpendicular to the main surface of the substrate W. The shoulder portion RSd includes an upper end RSc1 of the side wall RSb. The upper end RSc1 may coincide with a lower end of the side wall defining the opening OP.

The recess RS may have an inner diameter smaller than an inner diameter of the opening OP. The recess RS may have the same inner diameter as the inner diameter of the opening OP at the upper end RSc1 of the side wall RSb. The recess RS may have an inner diameter smaller than the inner diameter of the opening OP at a position RSc2 below the upper end RSc1. The shoulder portion RSd may include the position RSc2. The shoulder portion RSd may be formed such that the inner diameter of the recess RS gradually becomes narrower from the upper end RSc1 of the side wall RSb toward the position RSc2. Alternatively, the recess RS may have an inner diameter smaller than the inner diameter of the opening OP at the upper end RSc1.

The second region R2 contains silicon and a material different from the material contained in the first region R1. The second region R2 may contain silicon and nitrogen (N). The second region R2 may contain silicon nitride (SiNₓ). x is a positive real number.

The substrate W may further include a mask MK having an opening MOP. The mask MK is located on the first region R1. The opening MOP of the mask MK communicates with the opening OP of the first region R1. The mask MK may include a carbon-containing film or a metal-containing film. The carbon-containing film may include an amorphous carbon film. The metal-containing film may include at least one selected from the group consisting of tungsten silicate (WSi), tungsten carbide (WC), and titanium nitride (TiN).

The substrate W may further include an underlying film UR. The underlying film UR is located below the second region R2. The underlying film UR may contain a material different from the materials contained in the first region R1 and the second region R2. The underlying film UR may contain silicon.

The substrate W may further include a plurality of protrusions GA. The plurality of protrusions GA are disposed between the second region R2 and the underlying film UR. The plurality of protrusions GA may be arranged along the upper surface of the underlying film UR. The plurality of protrusions GA may be covered by the second region R2. The bottom portion RSa of the recess RS may be disposed between the plurality of the protrusions GA adjacent to each other. The plurality of protrusions GA may be disposed to be spaced apart from the recess RS. Each projection GA may form a gate region of a transistor.

The method MT will be described with reference to FIGS. 4 to 7 by using, as an example, the case where the method MT is applied to the substrate W by using the plasma processing apparatus 1 in the above-described embodiment. Each of FIGS. 4 to 7 is a cross-sectional view illustrating one step of the etching method according to the exemplary embodiment. When the plasma processing apparatus 1 is used, the method MT can be performed in the plasma processing apparatus 1 in a manner that the controller 2 controls each unit of the plasma processing apparatus 1. In the method MT, as illustrated in FIG. 2, the substrate W on the substrate support 11 disposed in the plasma processing chamber 10 is processed.

As illustrated in FIG. 3, the method MT can include Steps ST1 to ST5. Steps ST1 to ST5 may be executed in order. Step ST4 may be executed in the same plasma processing chamber 10 as Step ST3. The method MT does not need to include at least one of Steps ST2 and ST5. The details will be described later, but first plasma generated from a first process gas is used in Step ST3, and second plasma generated from a second process gas is used in Step ST4.

### (Step ST1)

In Step ST1, a substrate W illustrated in FIG. 4 is provided. The substrate W may be supported by the substrate support 11 in the plasma processing chamber 10.

The substrate W may be provided in a state where the first region R1 is etched by performing etching in a self-aligned contact (SAC) step. The etching in the SAC step may be performed using the plasma processing apparatus 1. The etching in the SAC step may be performed in the same plasma processing chamber 10 as in Steps ST1 to ST5.

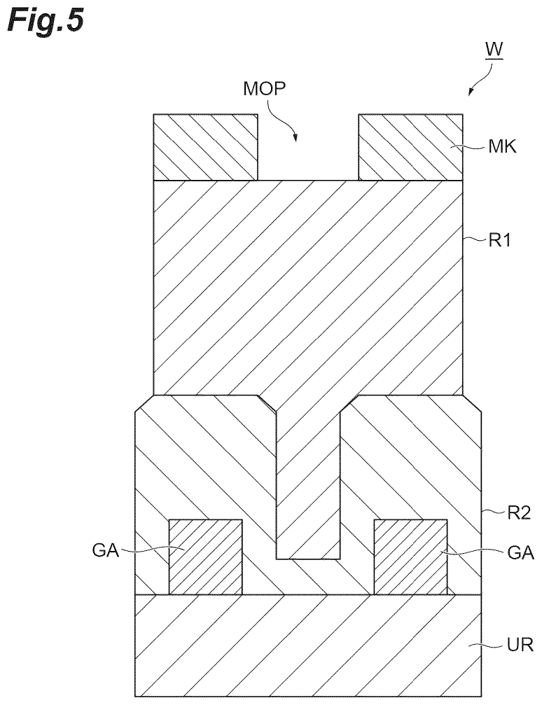

FIG. 5 illustrates a cross-sectional view of the substrate W before being etched in the SAC step. As illustrated in FIG. 5, before the etching in the SAC step, the first region R1 may be provided in the opening OP and the recess RS illustrated in FIG. 4. In the etching in the SAC step, the first region R1 provided in the opening OP and the recess RS may be etched with third plasma generated from a third process gas different from the first process gas and the second process gas. By etching the first region R1 through the opening MOP of the mask MK, the opening OP may be formed, and the recess RS may be exposed. In the etching in the SAC step, the opening OP and the recess RS may be formed such that the opening OP and the recess RS do not come into contact with the protrusion GA. In the substrate W etched in the SAC step, as illustrated in FIG. 4, the shoulder portion RSd may be exposed.

The third process gas may contain a fluorine-containing gas. The fluorine-containing gas may include at least one selected from the group consisting of a fluorocarbon gas (CₓF_{y} gas) and a hydrofluorocarbon gas (CₓH_{y}F_{z} gas). x, y, and z represent positive integers. The fluorocarbon gas may include at least one selected from the group consisting of a methane gas (CF₄ gas), a hexafluoropropene gas (C₃F₆ gas), a propane octafluoride gas (C₃F₈ gas), an octafluorocyclobutane gas (C₄F₈ gas), and a hexafluoro-1,3-butadiene gas (C₄F₆ gas). The hydrofluorocarbon gas may include at least one selected from the group consisting of a difluoromethane gas (CH₂F₂ gas), a trifluoromethane gas (CHF₃ gas), and a fluoromethane gas (CH₃F gas). The third process gas may further contain an oxygen-containing gas. The oxygen-containing gas may include an oxygen gas. The third process gas may further contain a noble gas.

### (Step ST2)

In Step ST2, the substrate W may be cleaned. In Step ST2, the residue generated by etching the first region R1 may be removed. In Step ST2, the substrate W may be cleaned with cleaning plasma generated from a cleaning gas in the plasma processing chamber 10. The cleaning gas may contain an oxygen-containing gas. The cleaning gas may contain a mixed gas including a nitrogen gas and a hydrogen gas.

### (Step ST3)

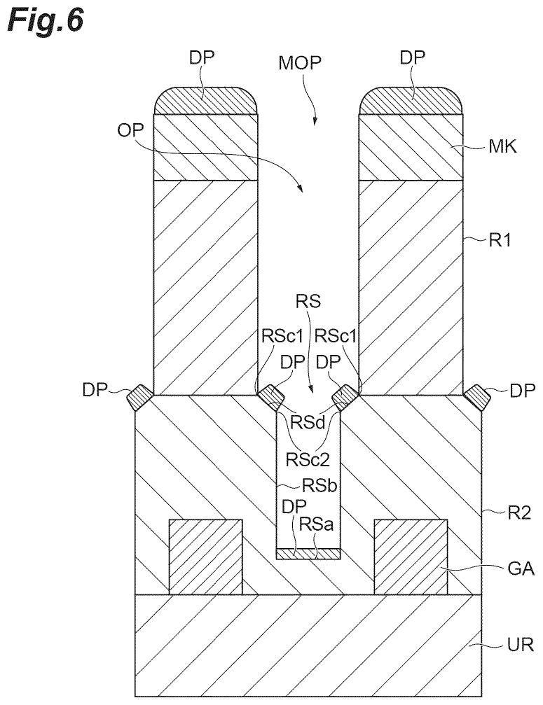

In Step ST3, as illustrated in FIG. 6, a deposit DP is formed on the shoulder portion RSd of the second region R2 with the first plasma generated from the first process gas. The deposit DP may contain carbon. FIG. 6 illustrates a cross-sectional view of the substrate W in Step ST3. In Step ST3, the deposit DP is preferentially formed on the shoulder portion RSd. As a result, in Step ST4 after Step ST3, the bottom portion RSa of the recess RS can be etched while protecting the shoulder portion RSd. In FIGS. 6, 7, and 9, the places where the deposit DP is formed are illustrated in an emphasized manner. The thickness of the deposit DP in FIGS. 6, 7, and 9 may be different from the actual thickness.

As illustrated in FIG. 6, in Step ST3, a deposit DP may be formed on the first region R1 or the mask MK in addition to the shoulder portion RSd. In Step ST3, the deposit DP may be formed on the bottom portion RSa of the recess RS. The thickness of the deposit DP formed on the shoulder portion RSd may be greater than the thickness of the deposit DP formed on the bottom portion RSa. The thickness of the deposit DP formed on the first region R1 or the mask MK may be greater than the thickness of the deposit DP formed on the shoulder portion RSd. When the thickness of the deposit DP on the bottom portion RSa is small, it is possible to accelerate etching of the bottom portion RSa in Step ST4. The ratio of the thickness of the deposit DP on the shoulder portion RSd with respect to the thickness of the deposit DP on the bottom portion RSa (thickness of the deposit DP on the shoulder portion DP/thickness of the deposit RSa on the bottom portion RSa; the ratio is referred to as an “M/B ratio” below) may be used as an evaluation index for the deposition of the deposit DP. The M/B ratio may be equal to or more than 3. The ratio of the thickness of the deposit DP on the bottom portion RSa with respect to the thickness of the deposit DP on the mask MK (thickness of the deposit DP on the bottom portion RSa/thickness of the deposit DP on the mask MK; the ratio is referred to as an “B/T ratio” below) may be used as another evaluation index for the deposition of the deposit DP. The B/T ratio may be equal to or less than 0.3 (equal to or less than 30%).

The first process gas contains carbon and oxygen. The gas containing carbon and oxygen may contain at least one selected from the group consisting of carbon monoxide (CO), carbon dioxide (CO₂), and carbonyl sulfide (COS). The first process gas may further contain a hydrogen-containing gas. The first process gas may further contain a gas containing carbon and hydrogen. The gas containing carbon and hydrogen may be a hydrocarbon gas (CxHy gas). x and y are positive integers. The hydrocarbon gas may be CH₄. The first process gas may be a hydrofluorocarbon gas. The hydrofluorocarbon gas may be a CH₃F gas. The first process gas may further contain a noble gas. The noble gas may be an argon gas (Ar gas).

In the first process gas, the flow rate of the gas containing carbon and oxygen may be greater than the flow rate of the gas containing carbon and hydrogen. In the first process gas, the flow rate of the gas containing carbon and oxygen may be three times or more the flow rate of the gas containing carbon and hydrogen. In the first process gas, the flow rate of the gas containing carbon and oxygen may be ten times or less the flow rate of the gas containing carbon and hydrogen. The flow rate of the gas containing carbon and oxygen may be 50 sccm or more and 120 sccm or less. The flow rate of the gas containing carbon and oxygen may be 80 sccm or more and 100 sccm or less. The flow rate of the gas containing carbon and hydrogen may be 5 sccm or more and 30 sccm or less. The flow rate of the gas containing carbon and hydrogen may be 10 sccm or more and 20 sccm or less.

### (Step ST4)

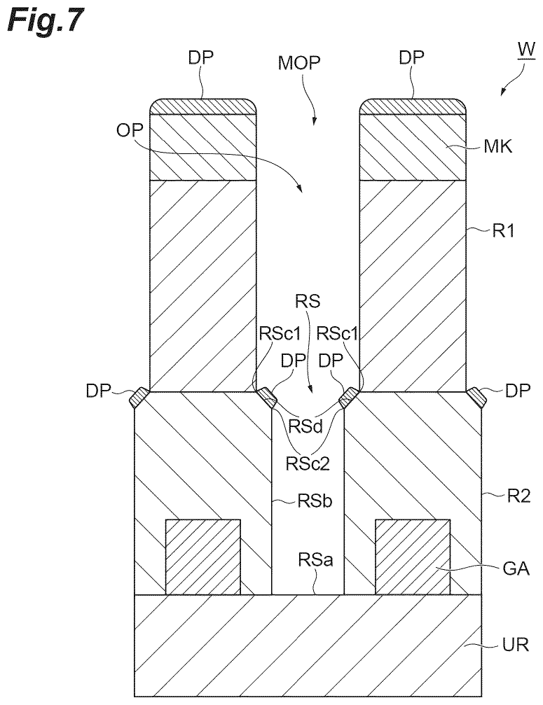

In Step ST4, the bottom portion RSa of the recess RS is etched by second plasma generated from the second process gas different from the first process gas. FIG. 7 illustrates a cross-sectional view of the substrate W in Step ST4. As illustrated in FIG. 7, in Step ST4, the bottom portion RSa may reach the underlying film UF. In Step ST4, the deposit DP on the shoulder portion RSd and the deposit DP on the mask MK may be etched. In Step ST4, the thickness of the deposit DP on the shoulder portion RSd and the thickness of the deposit DP on the mask MK may be reduced. In Step ST4, the deposit DP on the bottom portion RSa may be completely removed together with the etching of the bottom portion RSa.

The second process gas may contain a hydrogen-containing gas and a fluorine-containing gas. The hydrogen-containing gas may include a hydrogen gas. An example of the fluorine-containing gas contained in the second process gas may be the same as an example of the fluorine-containing gas contained in the third process gas. In the second process gas, the flow rate of the hydrogen-containing gas may be greater than the flow rate of the fluorine-containing gas. The second process gas does not need to contain the oxygen-containing gas.

### (Step ST5)

In Step ST5, Step ST2 and Step ST3 may be repeated. By repeating Steps ST2 and ST3, the bottom portion RSa can be etched as illustrated in FIG. 7 while replenishing the deposit DP on the shoulder portion RSd. In Step ST5, the substrate W may be cleaned before Step ST3. That is, when a step of executing Step ST3 and Step ST4 once each is set as one cycle, the next cycle may be started after the deposit DP is removed by cleaning the substrate W. The cleaning of the substrate W in Step ST5 may be performed in the same manner as in Step ST2.

According to the method MT, in Step ST3, the deposit DP is preferentially formed on the shoulder portion RSd of the second region R2. This makes it possible to etch the bottom portion RSa of the recess RS while protecting the shoulder portion RSd, in Step ST4.

In Step ST3, the first process gas may further contain a hydrogen-containing gas. In this case, it is possible to improve the etching resistance of the deposit DP. Thus, in Step ST4, it is possible to reduce a decrease in the thickness of the deposit DP. As a result, it is possible to suppress an occurrence of a situation in which the shoulder portion RSd is scraped or the mask MK is scraped.

In Step ST3, the first process gas may further contain a gas containing carbon and hydrogen. In this case, it is possible to thicken the thickness of the deposit DP deposited on the shoulder portion RSd. As a result, it is possible to thicken the remaining thickness of the deposit DP deposited on the shoulder portion RSd after Step ST4.

In Step ST3, the first process gas may contain a noble gas. In this case, it is possible to adjust the thickness of the deposit DP by adjusting the flow rate of the noble gas.

In Step ST3, the deposit DP may be formed on the first region R1 or the mask MK. In this case, it is possible to suppress an occurrence of a situation in which the first region R1 or the mask MK is scraped in Step ST4.

The method MT may further include Step ST5 of repeating Step ST3 and Step ST4. In this case, even when the deposit DP is scraped by the etching in Step ST4, it is possible to repeatedly add and deposit the deposit DP.

The method MT may include Step ST2 of cleaning the substrate W between Step ST1 and Step ST3. In this case, in Step ST3, it is possible to suppress blockage of the opening MOP, the opening OP, or the recess RS.

In the method MT, in Step ST5, the substrate W may be cleaned before Step ST3. In this case, in Step ST3 after cleaning the substrate W, it is possible to suppress the blockage of the opening MOP, the opening OP, or the recess RS.

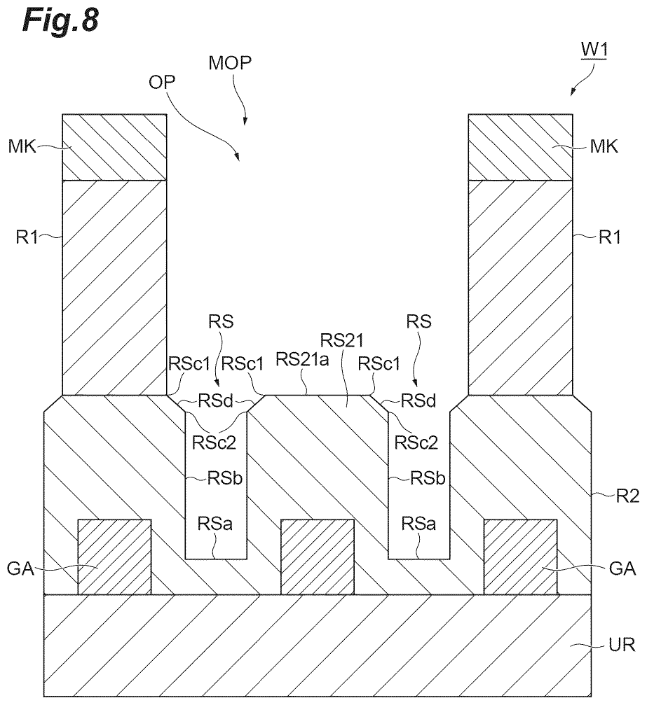

FIG. 8 is a cross-sectional view of a substrate W1 according to a modification example, to which the method MT may be applied. The substrate W1 may have the same configuration as the substrate W except for the following points. In the substrate W1, the second region R2 may have a plurality of recesses RS communicating with one opening OP. The second region R2 may include an intermediate region RS21. The intermediate region RS21 may be formed between the plurality of the recesses RS adjacent to each other. The intermediate region RS21 may cover the protrusion GA. The intermediate region RS21 may be located in the opening OP when viewed from a direction perpendicular to the main surface of the substrate W1. The intermediate region RS21 may have a plurality of shoulder portions RSd. The plurality of shoulder portions RSd include first and second shoulder portions RSd. The first shoulder portion RSd includes an upper end RSc1 of a side wall RSb of a first recess RS among the plurality of recesses RS. The second shoulder portion RSd includes an upper end RSc1 of a side wall RSb of a second recess RS among the plurality of recesses RS. The intermediate region RS21 has an upper surface RS21a extending between the first shoulder portion RSd and the second shoulder portion RSd. The first region R1 does not need to be formed on the intermediate region RS21. That is, the upper surface RS21a of the intermediate region RS21 may be exposed.

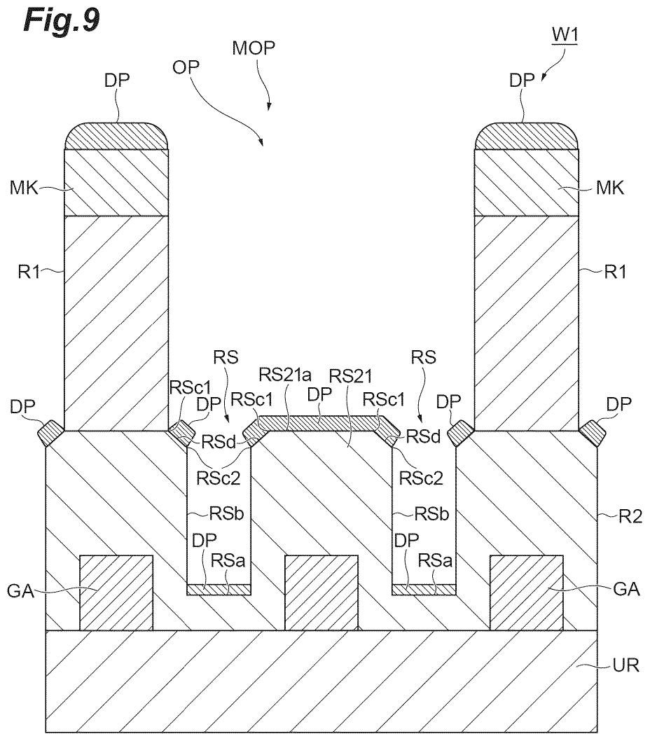

FIG. 9 is a cross-sectional view illustrating one step of an etching method when the method MT is applied to the substrate W1. FIG. 9 illustrates a cross-sectional view of the substrate W1 in Step ST3. The deposit DP may be formed on the shoulder portion RSd. The deposit DP may be formed on the mask MK. The deposit DP may be formed on the bottom portion RSa of the recess RS. Furthermore, with respect to the substrate W1, the deposit DP may be formed on the upper surface RS21a of the intermediate region RS21. The deposit DP may be continuously formed from the shoulder portion RSd to the upper surface RS21a of the intermediate region RS21.

When the method MT is applied to the substrate W1, in Step ST3, the deposit DP is preferentially formed on the shoulder portion RSd of the second region R2 and the upper surface RS21a of the intermediate region RS21. This makes it possible to etch the bottom portion RSa of the recess RS while protecting the shoulder portion RSd and the upper surface RS21a of the intermediate region RS21 in Step ST4.

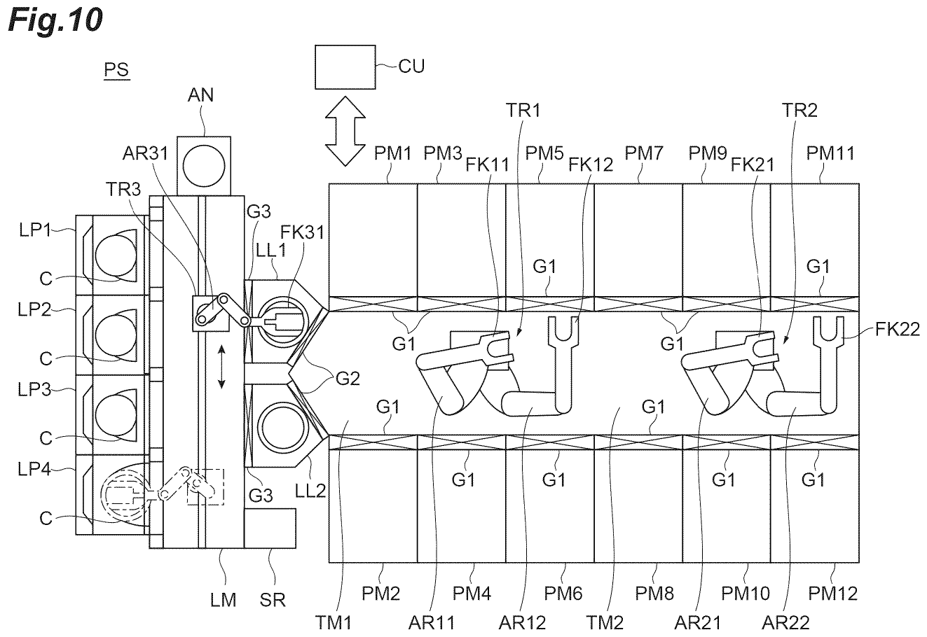

FIG. 10 is a schematic diagram illustrating a substrate processing system PS according to the exemplary embodiment. As illustrated in FIG. 10, the substrate processing system PS is a system that can perform various types of processing such as plasma processing on the substrate W or the substrate W1. The method MT can be applied to the substrate W or the substrate W1 by using the substrate processing system PS.

The substrate processing system PS includes vacuum transport modules TM1 and TM2, process modules PM1 to PM12, load lock modules LL1 and LL2, an atmosphere transport module LM, an aligner AN, a storage SR, and the like.

Each of the vacuum transport modules TM1 and TM2 has a substantially square shape in a plan view. The process modules PM1 to PM6 are connected to two side surfaces facing each other in the vacuum transport module TM1. Among two other side surfaces facing each other in the vacuum transport module TM1, the load lock modules LL1 and LL2 are connected to one side surface, and a path (not illustrated) for connection to the vacuum transport module TM2 is connected to the other side surface. The side surface of the vacuum transport module TM1 to which the load lock modules LL1 and LL2 are connected has an angle according to the two load lock modules LL1 and LL2. In the vacuum transport module TM2, the process modules PM7 to PM12 are connected to two side surfaces facing each other. A path (not illustrated) for connection to the vacuum transport module TM1 is connected to one side surface among two other side surfaces facing each other in the vacuum transport module TM2. The vacuum transport modules TM1 and TM2 have a vacuum chamber with a vacuum atmosphere, and vacuum transport robots TR1 and TR2 are disposed in the vacuum transport modules TM1 and TM2, respectively.

The vacuum transport robots TR1 and TR2 are configured to freely swivel, expand and contract, and move up and down. The vacuum transport robots TR1 and TR2 transport a transport target object based on an operation instruction output from a controller CU, which will be described later. For example, the vacuum transport robot TR1 holds the transport target object by forks FK11 and FK12 disposed at the tip, and transports the transport target object between the load lock modules LL1 and LL2, the process modules PM1 to PM6, and a path (not illustrated). For example, the vacuum transport robot TR2 holds the transport target object by forks FK21 and FK22 disposed at the tip, and transports the transport target object between the process modules PM7 to PM12, and a path (not illustrated). The fork is also referred to as a pick or an end effector.

The transport target object includes the substrate W and consumable members. The consumable member is a member that is replaceably mounted in the process modules PM1 to PM12 and is consumed by performing various types of processing such as plasma processing in the process modules PM1 to PM12. The consumable member includes, for example, members constituting a ring assembly 112 and a shower head 13, which will be described later.

The process modules PM1 to PM12 include a processing chamber and a stage (placement table) that is disposed inside. In the process modules PM1 to PM12, after the substrates W are installed on the stage, the internal pressure is reduced, and the process gas is introduced. Then, R power is applied to generate plasma, and the substrate is subjected to plasma processing with the plasma. The vacuum transport modules TM1 and TM2 and the process modules PM1 to PM12 are partitioned by a gate valve G1 that can be opened and closed.

The load lock modules LL1 and LL2 are disposed between the vacuum transport module TM1 and the atmosphere transport module LM. The load lock modules LL1 and LL2 include an internal pressure variable chamber having an inside that can be switched between vacuum and atmospheric pressure. The load lock modules LL1 and LL2 have a stage disposed inside. When the substrate W is carried from the atmosphere transport module LM to the vacuum transport module TM1, the load lock modules LL1 and LL2 receive the substrate W from the atmosphere transport module LM while maintaining the inside at atmospheric pressure. Then, the load lock modules LL1 and LL2 reduce the internal pressure and carry the substrate W into the vacuum transport module TM1. When the substrate W is carried out from the vacuum transport module TM1 to the atmosphere transport module LM, the load lock modules LL1 and LL2 receive the substrate W from the vacuum transport module TM1 while maintaining the vacuum inside. Then, the load lock modules LL1 and LL2 boost the inside to atmospheric pressure and carry the substrate into the atmosphere transport module LM. The load lock modules LL1 and LL2 and the vacuum transport module TM1 are partitioned by a gate valve G2 that can be opened and closed. The load lock modules LL1 and LL2 and the atmosphere transport module LM are partitioned by a gate valve G3 that can be opened and closed.

The atmosphere transport module LM is disposed to face the vacuum transport module TM1. The atmosphere transport module LM may be, for example, an equipment front end module (EFEM). The atmosphere transport module LM is an atmosphere transport chamber that has a rectangular parallelepiped shape, includes a fan filter unit (FFU), and is maintained in an atmospheric pressure atmosphere. The two load lock modules LL1 and LL2 are connected to one side surface of the atmosphere transport module LM along a longitudinal direction thereof. Load ports LP1 to LP4 are connected to the other side surface of the atmosphere transport module LM along the longitudinal direction. A container C that accommodates a plurality of (for example, 25 pieces) substrates W are placed on the load ports LP1 to LP4. The container C may be, for example, a front-opening unified pod (FOUP). An atmosphere transport robot TR3 that transports a transport target object is disposed in the atmosphere transport module LM.

The atmosphere transport robot TR3 is configured to be movable along the longitudinal direction of the atmosphere transport module LM, and is configured to freely swivel, expand and contract, and move up and down. The atmosphere transport robot TR3 transports a transport target object based on an operation instruction output from the controller CU, which will be described later. For example, the atmosphere transport robot TR3 holds the transport target object by a fork FK31 disposed at the tip, and transports the transport target object between the load ports LP1 to LP4, the load lock modules LL1 and LL2, the aligner AN, and the storage SR.

The aligner AN is connected to one side surface of the atmosphere transport module LM along a short side direction. However, the aligner AN may be connected to a side surface of the atmosphere transport module LM along the longitudinal direction. In addition, the aligner AN may be provided inside the atmosphere transport module LM. The aligner AN includes a support stand, an optical sensor (none of which is not illustrated), and the like. The aligner referred to here is a device that detects a position of a transport target object.

The support stand is a stand that can rotate around an axis extending in the vertical direction, and is configured to support the substrate W on the support stand. The support stand is rotated by a drive device (not illustrated). The drive device is controlled by the controller CU which will be described later. When the support stand is rotated by power from the drive device, the substrate installed on the support stand is also rotated.

The optical sensor detects an edge of the substrate while the substrate rotates. The optical sensor detects the deviation amount of an angle position of a notch (or another marker) of the substrate with respect to a reference angle position and the deviation amount of the center position of the substrate with respect to a reference position, from the detection result of the edge. The optical sensor outputs the deviation amount of the angle position of the notch and the deviation amount of the center position of the substrate to the controller CU which will be described later. The controller CU calculates a rotation amount of a rotation support stand for correcting the angle position of the notch to the reference angle position based on the deviation amount of the angle position of the notch. The controller CU controls the drive device (not illustrated) to rotate the rotation support stand by the rotation amount. As a result, it is possible to correct the angle position of the notch to the reference angle position. In addition, the controller CU sets the position of the fork FK31 of the atmosphere transport robot TR3 when receiving the substrate W from the aligner AN, based on the deviation amount of the center position of the substrate W so that the center position of the substrate coincides with a predetermined position on the fork FK31 of the atmosphere transport robot TR3.

The storage SR is connected to the side surface of the atmosphere transport module LM along the longitudinal direction. However, the storage SR may be connected to the side surface of the atmosphere transport module LM along the short side direction. In addition, the storage SR may be provided inside the atmosphere transport module LM. The storage SR accommodates the transport target object.

The substrate processing system PS is provided with the controller CU. The controller CU may be, for example, a computer. The controller CU includes a central processing unit (CPU), a random access memory (RAM), a read only memory (ROM), an auxiliary storage device, and the like. The CPU operates based on a program stored in the ROM or the auxiliary storage device and controls each unit of the substrate processing system PS. For example, the controller CU outputs operation instructions to the vacuum transport robots TR1 and TR2, the atmosphere transport robot TR3, and the like. The operation instruction includes an instruction for aligning the forks FK11, FK12, FK21, FK22, and FK31 for transporting the transport target object with a transport place of the transport target object.

In the method MT, Step ST3 may be executed in a first chamber. In this case, Step ST4 may be executed in a second chamber different from the first chamber. An example of the first chamber is one of the chambers of the process modules PM1 to PM12. An example of the second chamber is any chamber of the process modules PM1 to PM12 excluding the process module corresponding to the first chamber. In the method MT, Steps ST1 to ST5 may be executed in different chambers. For example, Step ST1 may be executed in the process module PM1. Step ST2 may be executed in the process module PM2. Step ST3 may be executed in the process module PM3. Step ST4 may be executed in the process module PM4. Step ST5 may be executed in the process module PM5. After one step is ended, the substrate W or the substrate W1 may be transported to another process module by the vacuum transport module TM1.

Although the various exemplary embodiments have been described above, various additions, omissions, substitutions, and changes may be made without being limited to the exemplary embodiments described above. Other embodiments can be formed by combining elements in different embodiments.

A first experiment to an eleventh experiment performed for evaluating Step ST3 in the method MT will be described below. The experiments described below do not limit the present disclosure.

### First Experiment

In the first experiment, a substrate having the same structure as the substrate W illustrated in FIG. 4 was prepared. The first region R1 is a silicon oxide film. The second region R2 is a silicon nitride film. Then, the deposit DP was formed on the shoulder portion RSd of the second region R2 with the first plasma generated from the first process gas (Step ST3). The first process gas is a mixed gas of an H₂ gas, a CO gas, and an Ar gas. The flow rate of the CO gas is 7.5 times the flow rate of the H₂ gas. The processing time of Step ST3 is 60 seconds. The first experiment to the fifth experiment were performed in a state where the deposit DP had already been deposited on the bottom portion RSa of the recess RS before Step ST3 is executed. In the subsequent second to eleventh experiments, the conditions are the same as those in the first experiment except for the first process gas and the processing time of Step ST3.

### Second Experiment

The first process gas is a mixed gas of a COS gas, a CO gas, and an Ar gas. The flow rate of the CO gas is 23 times the flow rate of the COS gas. The processing time of Step ST3 is 60 seconds.

### Third Experiment

The first process gas is a mixed gas of a CH₄ gas, a CO gas, and an Ar gas. The flow rate of the CO gas is 4.5 times the flow rate of the CH₄ gas. The processing time of Step ST3 is 30 seconds.

### Fourth Experiment

The first process gas is a mixed gas of a CH₄ gas, a CO gas, and an Ar gas. The flow rate of the CO gas is 9.0 times the flow rate of the CH₄ gas. The processing time of Step ST3 is 60 seconds.

### Fifth Experiment

The first process gas is a mixed gas of a CH₃F gas and an Ar gas. The processing time of Step ST3 is 30 seconds.

### Experimental Results of First Experiment to Fifth Experiment

In each of the first experiment to the fifth experiment, a cross section of the substrate was observed. In the cross section, the amount of change before and after Step ST3 was measured for the thickness of the deposit DP on the mask MK, the thickness of the deposit DP on the shoulder portion RSd, and the thickness of the deposit DP on the bottom portion RSa of the recess RS.

In the first experiment, the amount of change in the thickness of the deposit DP on the mask MK (referred to as an “amount of change on the mask MK” below) was +10.4 nm. The amount of change in the thickness of the deposit DP on the shoulder portion RSd (referred to as an “amount of change on the shoulder portion RSd” below) was +0.5 nm. The amount of change in the thickness of the deposit DP on the bottom portion RSa (referred to as an “amount of change on the bottom portion RSa” below) was −2.7 nm. Here, it is presumed that the reason for the decrease in the thickness of the deposit DP on the bottom portion RSa is that the deposit DP has been removed because the first process gas contains the H₂ gas. In the second experiment, the amount of change on the mask MK was +11.9 nm, the amount of change on the shoulder portion RSd was +2.2 nm, and the amount of change on the bottom portion RSa was +2.0 nm. In the third experiment, the amount of change on the mask MK was +11.5 nm, the amount of change on the shoulder portion RSd was +2.6 nm, and the amount of change on the bottom portion RSa was +1.2 nm. In the fourth experiment, the amount of change on the mask MK was +19.0 nm, the amount of change on the shoulder portion RSd was +4.6 nm, and the amount of change on the bottom portion RSa was +1.2 nm. In the fifth experiment, the amount of change on the mask MK was +3.4 nm, the amount of change on the shoulder portion RSd was +3.0 nm, and the amount of change on the bottom portion RSa was +2.5 nm.

In the fourth experiment among the first experiment to the fifth experiment, the ratio (M/B ratio) of the thickness of the deposit DP on the shoulder portion RSd with respect to the thickness of the deposit DP on the bottom portion RSa was the highest. In the fourth experiment, the M/B ratio was 3.1 (+4.6 nm/+1.2 nm).

### Sixth Experiment to Tenth Experiment

In the subsequent sixth to tenth experiments, the first process gas is a mixed gas of a CH₄ gas, a CO gas, and an Ar gas. The processing time of Step ST3 is 60 seconds. The experiment was performed by changing only the flow rate of the CH₄ gas.

### Sixth Experiment

The flow rate of the CO gas is 7.5 times the flow rate of the CH₄ gas.

### Seventh Experiment

The flow rate of the CO gas is three times the flow rate of the CH₄ gas.

### Eighth Experiment

The flow rate of the CO gas is 2.1 times the flow rate of the CH₄ gas.

### Ninth Experiment

The flow rate of the CO gas is one time the flow rate of the CH₄ gas.

### Tenth Experiment

The flow rate of the CO gas is 0.3 times the flow rate of the CH₄ gas.

### Experimental Results of Sixth Experiment to Tenth Experiment

In each of the sixth experiment to the tenth experiment, the amount of change before and after Step ST3 was measured for the thickness of the deposit DP on the mask MK and the thickness of the deposit DP on the bottom portion RSa of the recess RS. Then, the ratio (B/T ratio) of the thickness of the deposit DP on the bottom portion RSa with respect to the thickness of the deposit DP on the mask MK was calculated. In the sixth experiment, the B/T ratio was 29%. In the seventh experiment, the B/T ratio was 33%. In the eighth experiment, the B/T ratio was 36%. In the ninth experiment, the B/T ratio was 58%. In the tenth experiment, the B/T ratio was 94%. It was found that the smaller the flow rate ratio of the CH₄ gas, the lower the B/T ratio.

### First Experiment, Third Experiment, Fifth Experiment, and Eleventh Experiment

In addition to the first experiment, the third experiment, and the fifth experiment, the eleventh experiment was performed, and it was evaluated whether or not the performance of the deposit DP on the mask MK changes depending on the type of the first process gas. In the eleventh experiment, the first process gas is a mixed gas of a CO gas and an Ar gas. The processing time of Step ST3 is 60 seconds.

### Experimental Results of First Experiment, Third Experiment, Fifth Experiment, and Eleventh Experiment

In the first experiment, the third experiment, the fifth experiment, and the eleventh experiment, it was observed whether or not the opening OP has been blocked after Step ST3. Furthermore, after Step ST3, etching of Step ST4 was performed to evaluate the etching resistance of the deposit DP on the mask MK. The etching resistance can be evaluated, for example, by the amount of decrease in the thickness of the deposit DP on the mask MK before and after Step ST4. When the amount of decrease is small, the etching resistance is high. In the fifth experiment, the blockage of the opening OP was confirmed. The etching resistance was evaluated to be high. In the first experiment, the blockage of the opening OP was not confirmed. The etching resistance was evaluated to be lower than the result of the fifth experiment. In the third experiment, the blockage of the opening OP was not confirmed. The etching resistance was evaluated to be equivalent to the result of the fifth experiment. In the eleventh experiment, the blockage of the opening OP was not confirmed. The etching resistance was evaluated to be the lowest. Based on the above results, it was found that, when the mixed gas (first experiment) of an H₂ gas and a CO gas, the mixed gas (third experiment) of a CH₄ gas and a CO gas, and the CO gas (eleventh experiment) were used for the first process gas, the opening OP is not blocked. It was found that, when the first process gas contains a hydrogen-containing gas (first experiment, the third experiment, and the fifth experiment), the etching resistance of the deposit DP on the mask MK was higher than the etching resistance when first process gas does not contain the hydrogen-containing gas (eleventh experiment).

Here, the various exemplary embodiments included in the present disclosure are described in [E1] to [E20] below.

### [E1]

An etching method comprising:
(a) providing a substrate including a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region;
(b) forming a deposit on the shoulder portion with first plasma generated from a first process gas containing a gas containing carbon and oxygen; and
(c) etching a bottom portion of the recess with second plasma generated from a second process gas different from the first process gas.

### [E2]

The etching method described in [E1],
in which the first process gas further contains a hydrogen-containing gas.

### [E3]

The etching method described in [E1] or [E2],
in which the first process gas further contains a gas containing carbon and hydrogen.

### [E4]

The etching method described in [E3],
in which the gas containing carbon and hydrogen is a hydrocarbon gas.

### [E5]

The etching method described in [E1] or [E4],
in which, in (b), a flow rate of the gas containing carbon and oxygen is greater than a flow rate of the gas containing carbon and hydrogen.

### [E6]

The etching method described in any one of [E3] to [E5],
in which, in (b), a flow rate of the gas containing carbon and oxygen is three times or more a flow rate of the gas containing carbon and hydrogen.

### [E7]

The etching method described in [E6],
in which, in (b), the flow rate of the gas containing carbon and oxygen is ten times or less the flow rate of the gas containing carbon and hydrogen.

### [E8]

The etching method described in any one of [E1] to [E7],
in which the gas containing carbon and oxygen includes at least one selected from the group consisting of CO, CO₂, and COS.

### [E9]

The etching method described in any one of [E1] to [E8],
in which the first process gas further contains a noble gas.

### [E10]

The etching method described in any one of [E1] to [E9],
in which the second process gas contains a hydrogen-containing gas and a fluorine-containing gas.

### [E11]

The etching method described in any one of [E1] to [E10],
in which, in (b), the deposit is formed on the first region.

### [E12]

The etching method described in any one of [E1] to [E11], further comprising:
(d) repeating (b) and (c).

### [E13]

The etching method described in [E12],
in which, in (d), the substrate is cleaned before (b).

### [E14]

The etching method described in any one of [E1] to [E13], further comprising: (e) cleaning the substrate between (a) and (b).

### [E15]

The etching method described in any one of [E1] to [E14],
in which (a) includes etching the first region provided in the opening and the recess with third plasma generated from a third process gas different from the first process gas and the second process gas.

### [E16]

The etching method described in [E15],
in which the second process gas does not contain an oxygen-containing gas.

### [E17]

The etching method described in [E16],
in which the third process gas contains the oxygen-containing gas.

### [E18]

The etching method described in any one of [E1] to [E17],
in which (b) and (c) are performed in the same chamber.

### [E19]

The etching method described in any one of [E1] to [E18],
in which (b) is performed in a first chamber, and (c) is performed in a second chamber different from the first chamber.

### [E20]

A plasma processing apparatus comprising:
a chamber;
a substrate support for supporting a substrate in the chamber;
a gas supply configured to supply a first process gas that contains a gas containing carbon and oxygen and a second process gas different from the first process gas into the chamber;
a plasma generator configured to generate first plasma from the first process gas and generate second plasma from the second process gas; and
a controller,
wherein the substrate includes a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region, and
the controller is configured to control the gas supply and the plasma generator to
   form a deposit on the shoulder portion with the first plasma, and
   etch a bottom portion of the recess with the second plasma.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a substrate including a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region;
(b) forming a deposit on the shoulder portion with first plasma generated from a first process gas containing a gas containing carbon and oxygen; and
(c) etching a bottom portion of the recess with second plasma generated from a second process gas different from the first process gas.

2. The etching method according to claim 1,
wherein the first process gas further contains a hydrogen-containing gas.

3. The etching method according to claim 1,
wherein the first process gas further contains a gas containing carbon and hydrogen.

4. The etching method according to claim 3,
wherein the gas containing carbon and hydrogen is a hydrocarbon gas.

5. The etching method according to claim 3,
wherein, in (b), a flow rate of the gas containing carbon and oxygen is greater than a flow rate of the gas containing carbon and hydrogen.

6. The etching method according to claim 3,
wherein, in (b), a flow rate of the gas containing carbon and oxygen is three times or more a flow rate of the gas containing carbon and hydrogen.

7. The etching method according to claim 6,
wherein, in (b), the flow rate of the gas containing carbon and oxygen is ten times or less the flow rate of the gas containing carbon and hydrogen.

8. The etching method according to claim 1,
wherein the gas containing carbon and oxygen includes at least one selected from the group consisting of CO, CO₂, and COS.

9. The etching method according to claim 1,
wherein the first process gas further contains a noble gas.

10. The etching method according to claim 1,
wherein the second process gas contains a hydrogen-containing gas and a fluorine-containing gas.

11. The etching method according to claim 1,
wherein, in (b), the deposit is formed on the first region.

12. The etching method according to claim 1, further comprising:
(d) repeating (b) and (c).

13. The etching method according to claim 12,
wherein, in (d), the substrate is cleaned before (b).

14. The etching method according to claim 1, further comprising:
(e) cleaning the substrate between (a) and (b).

15. The etching method according to claim 1,
wherein (a) includes etching the first region provided in the opening and the recess with third plasma generated from a third process gas different from the first process gas and the second process gas.

16. The etching method according to claim 15,
wherein the second process gas does not contain an oxygen-containing gas.

17. The etching method according to claim 16,
wherein the third process gas contains the oxygen-containing gas.

18. The etching method according to claim 1,
wherein (b) and (c) are performed in the same chamber.

19. The etching method according to claim 1,
wherein (b) is performed in a first chamber, and (c) is performed in a second chamber different from the first chamber.

20. A plasma processing apparatus comprising:
a chamber;
a substrate support for supporting a substrate in the chamber;
a gas supply configured to supply a first process gas that contains a gas containing carbon and oxygen and a second process gas different from the first process gas into the chamber;
a plasma generator configured to generate first plasma from the first process gas and generate second plasma from the second process gas; and
a controller,
wherein the substrate includes a first region having an opening and a second region located below the first region, the second region including a recess communicating with the opening, when viewed from a direction perpendicular to a main surface of the substrate, the second region including a shoulder portion located in the opening, the shoulder portion including an upper end of a side wall of the recess, the second region containing silicon and a material different from a material contained in the first region, and
the controller is configured to control the gas supply and the plasma generator to
form a deposit on the shoulder portion with the first plasma, and
etch a bottom portion of the recess with the second plasma.
